(19) United States
(12) Patent Application Publication
(10) Pub. No.: US 2023/0045618 A1
(43) Pub. Date: Feb. 9, 2023

(54) DISPLAY DEVICE

(71) Applicant: LG Display Co., Ltd., Seoul (KR)

(72) Inventors: Hyun Jin KIM, Paju-si (KR); Sun Wook KO, Paju-si (KR); Kum Mi OH, Paju-si, (KR); Seung Hyo KO, Paju-si (KR)

(21) Appl. No.: 17/789,765

(22) PCT Filed: Oct. 27, 2020
(86) PCT No.: PCT/KR2020/014706

§ 371 Date: Jun. 28, 2022

(30) Foreign Application Priority Data
Dec. 30, 2019 (KR) 10-2019-0178635

(51) Int. Cl. H01L 33/38; H01L 25/075; H01L 33/62; H01L 33/40

(52) U.S. Cl. CPC H01L 33/382; H01L 25/0753; H01L 33/62; H01L 33/40

(57) ABSTRACT

A display device according to one embodiment of the present disclosure may include a substrate including a plurality of concave portions, light emitting elements disposed at the plurality of concave portions, a first insulating layer disposed on the substrate and the light emitting element, a transistor disposed on the first insulating layer and including an active electrode and a gate electrode, a first hole included in the active electrode, a second hole included in the first insulating layer, and a connection electrode disposed in the first hole and the second hole, wherein the light emitting element may be electrically connected to the active electrode by the connection electrode.

### BACKGROUND

### Technical Field

This application relates to a display device, and particularly, to a display device including a structure that is capable of implementing a high resolution.

### Description of the Related Art

Presently, with the advent of an information age, a field of a display device visually displaying electrical information signals has advanced rapidly, and a research to develop performances of thin profile, light weight, low power consumption and so on for various display devices has continued.

Among the various display devices, a light emitting display device is a self-luminescent type display device and can be manufactured in light weight and thin profile because it does not need a light source unlike a liquid crystal display device. Furthermore, a light emitting display device is advantageous in terms of power consumption because of its low voltage driving and is also excellent in color implementation, response speed, viewing angle and contrast ration (CR), and is thus expected to be used in various fields.

### BRIEF SUMMARY

As a light emitting display device, a display device, which is manufactured by transferring a light emitting diode (LED) to a thin film transistor array substrate, has been used. The LED has a fast lighting speed, and further, has a low power consumption, has an excellent stability due to a strong impact resistance, and is able to display an image of a high brightness, and thus the LED is a light emitting element drawing an attention.

A display device uses a small-sized LED such as a mini LED, a micro-sized LED such as a micro LED, or the like. The micro LED (μLED) is a micro-sized LED a size of which is 100 um or less, and recently, a research to develop a display device of a high resolution using a micro LED has proceeded actively.

A display device can be applied to a virtual reality (VR) or augmented reality (AR) device, and thus an interest in high resolution is growing bigger. However, a current structure of display device has limitations in meeting the rapidly changing needs of the market.

The present disclosure is to solve the above problems, and inventors of the present disclosure has invented a display device capable of a high resolution.

In order to achieve the object as described above, a display device according to one embodiment of the present disclosure may include a substrate including a plurality of concave portions, light emitting elements disposed at the plurality of concave portions, a first insulating layer disposed on the substrate and the light emitting element, a transistor disposed on the first insulating layer and including an active electrode and a gate electrode, a first hole included in the active electrode, a second hole included in the first insulating layer, and a connection electrode disposed in the first hole and the second hole, wherein the light emitting element may be electrically connected to the active electrode by the connection electrode.

Furthermore, a display device according to another embodiment of the present disclosure may include a substrate, a light emitting element and a transistor disposed on the substrate, a first electrode electrically connected to a first semiconductor layer of the light emitting element, a second electrode electrically connected to a second semiconductor layer of the light emitting element, and a connection electrode electrically connected to one of the first electrode and the second electrode, wherein the connection electrode may be electrically connected to an active electrode of the transistor, and wherein the connection electrode may penetrate at least a part of the active electrode.

Details of other embodiments are included in the detailed explanations and drawings.

The present disclosure can further improve a resolution by newly suggesting a connection structure of a light emitting element and a driving circuit.

Furthermore, the present disclosure can improve a pixel arrangement efficiency by arranging a driving circuit to overlap a light emitting element.

Furthermore, the present disclosure can minimize an unnecessary space by enabling electrical connection between a light emitting element and a driving circuit through a vertical through hole.

Effects according to the present disclosure are not limited by the contents exemplified above, and more various effects are included in the present specification.

### BRIEF DESCRIPTION OF THE SEVERAL VIEWS OF THE DRAWINGS

FIG. 1 is a schematic plan view of a display device according to one embodiment of the present disclosure.

FIG. 2 is a cross-sectional view of a pixel shown in FIG. 1.

FIG. 3 is a cross-sectional view enlarging a portion of a pixel shown in FIG. 2.

FIGS. 4 to 12 are process views of a display device according to one embodiment of the present disclosure.

FIGS. 13 to 18 are process views of an LED according to one embodiment of the present disclosure.

FIG. 19 is a cross-sectional view of a pixel according to another embodiment of the present disclosure.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the embodiments of the present disclosure are illustrative, and the present disclosure is not limited to the illustrated matters. Furthermore, in describing the present disclosure, if it is determined that a detailed description of the related known technology unnecessarily obscure the subject matter of the present disclosure, the detailed description thereof can be omitted. When ‘including,’ ‘having,’ ‘consisting,’ and the like are used in this disclosure, other parts may be added unless ‘only’ is used. When a component is expressed in the singular, cases including the plural are included unless specific statement is described.

In interpreting the components, even if there is no separate explicit description, it is interpreted as including a margin range.

In the case of a description of the positional relationship, for example, when the positional relationship of two parts is described as ‘on,’ ‘over,’ ‘under,’ ‘on a side surface,’ and the like, one or more other parts may be positioned between two parts unless ‘right’ or ‘directly’ is described.

What is referred to as an element or layer being on another element or layer includes all cases with yet another layer or yet another element interposed directly on the another element or in the middle therebetween.

Furthermore, although a first, a second and the like are used to describe various components, these components are not limited by these terms. These terms are only used to distinguish one component from another component. Therefore, a first component mentioned below may be a second component within the technical spirit of the present disclosure.

Size and thickness of each component shown in the drawings are illustrated for convenience of description, and the present disclosure is not necessarily limited to the size and thickness of the illustrated component.

Respective features of various embodiments of the present disclosure can be partially or wholly connected to or combined with each other and can be technically interlocked and driven variously, and respective embodiments may be independently implemented from each other or may be implemented together with a related relationship.

Hereinafter, the present disclosure is explained with reference to the drawings.

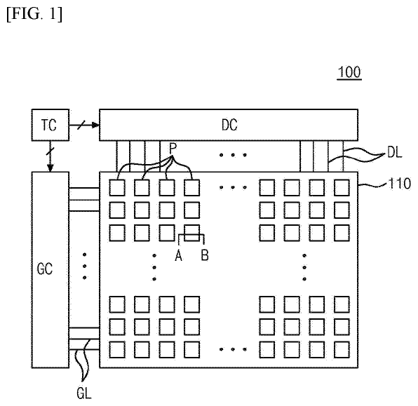

FIG. 1 is a schematic plan view of a display device according to one embodiment of the present disclosure.

The display device 100 includes a substrate 110, a gate driving portion GC, a data driving portion DC, and a timing controller TC.

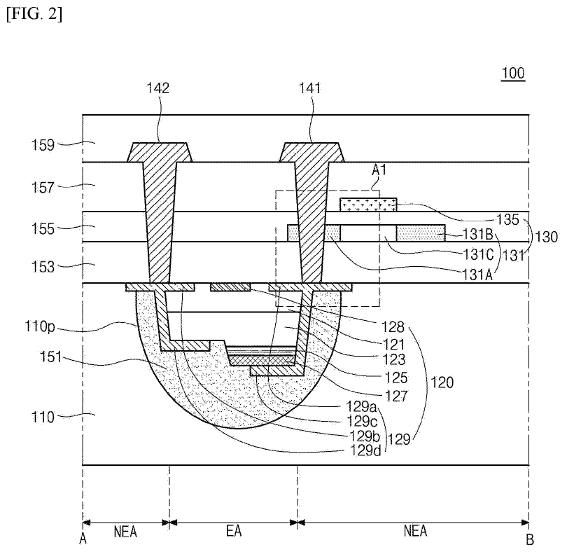

The display device 100 may include various circuits, lines and light emitting diodes disposed on the substrate 110. The substrate 110 include a plurality of pixels P, and the pixels P may be divided by a plurality of data lines DL and a plurality of gate lines GL crossing each other. The substrate 110 may be divided into a display area including the plurality of pixels P and a non-display area where various signal lines, pads and the like are formed. Each pixel P may include a light emitting diode (LED) (120 of FIG. 2) as a light emitting element, and for example, a micro LED (μLED) having a size of 100 um or less may be used. The pixel P shown in FIG. 1 may include a plurality of sub-pixels. Each of the plurality of sub-pixels may include an LED 120, and a plurality of LEDs 120 included in one pixel P may emit different colors. A pixel P, which can realize all colors that a display device 100 can display, is referred to as a unit pixel, and in this case, the unit pixel may correspond to the pixel P shown in FIG. 1.

The pixel P may include a pixel driving circuit. The pixel driving circuit may include at least one driving transistor and at least one switching transistor. The LED 120, which is a light emitting element of the pixel P, may be electrically connected to the pixel driving circuit and emit a light according to a data voltage (Vdata). In the specification of the present disclosure, for the convenience of explanations, a driving circuit including one transistor is explained, but it is not limited.

Timing signals of a vertical synchronization signal, a horizontal synchronization signal, a data enable signal, a dot clock and the like are input to the timing controller TC through a receiving circuit of an LVDS or TMDS interface connected to a host system. Based on the input timing signals, the timing controller TC generates timing control signals to control the data driving portion DC and the gate driving portion GC.

The data driving portion DC is connected to the plurality of data lines DL of the display device 100 and supplies the plurality of pixels with the data voltages (Vdata). The data driving portion DC may include a plurality of source drive ICs (Integrated Circuits). The plurality of source drive ICs may be supplied with digital video data (RGB) and source timing control signal (DDC) from the timing controller TC. In response to the source timing control signal, the plurality of source drive ICs may convert the digital video data (RGB) into gamma voltages to generate data voltages (Vdata) and supply the data voltages (Vdata) through the plurality of data lines DL of the display device 100. The plurality of source drive ICs may be connected to the plurality of data lines DL of the display device 100 by a COG (Chip On Glass) process or TAB (Tape Automated Bonding) process. Furthermore, the plurality of source drive ICs may have a structure that it is formed on a top surface of the substrate 110 or a bottom surface of the substrate 110, or that it is formed on a separate PCB substrate and is electrically connected to the substrate 110.

The gate driving portion GC is connected to the plurality of gate lines GL on the substrate 110 and supplies the plurality of pixels with gate signals. The gate driving portion GC may include a level shifter and a shift register. The level shifter may shift a level of a clock signal (CLK) input at a TTL (Transistor-Transistor-Logic) level from the timing controller TC and then supply it to the shift register. The shift register may be formed with a GIP type in the non-display area of the substrate 110, but it is not limited. The shift register may be configured with a plurality of stages which shift and output the gate signals in response to the clock signal and a driving signal. The plurality of stages included in the shift register may output the gate signals through a plurality of output terminals.

Meanwhile, the gate driving portion GC, the data driving portion DC and the timing controller TC may be disposed below the substrate 110, and a plurality of lines such as the gate lines GL and the data lines DL may be disposed at a side surface of the substrate 110. Accordingly, using the display device 100 of the present disclosure, it is possible to implement a tiling display device a bezel of which is not visible, and a size of a high resolution display can extend as desired.

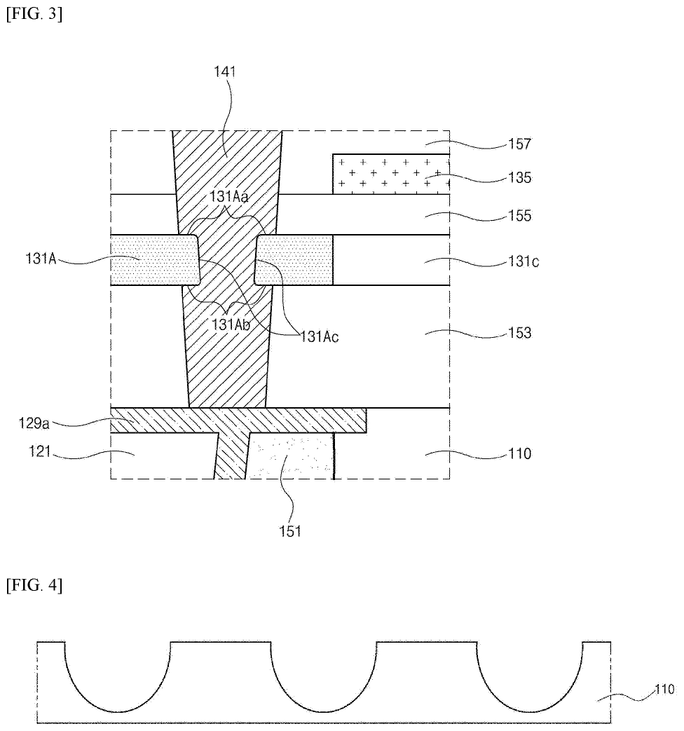

FIG. 2 is a cross-sectional view of a pixel shown in FIG. 1, and FIG. 3 is a cross-sectional view enlarging a portion of a pixel shown in FIG. 2. To facilitate explanations, one LED 120 of the plurality of LEDs 120 and one transistor 130 included in the pixel P are merely shown. The transistor 130 shown in FIG. 2 may be a driving transistor, but it is not limited.

The display device 100 according to one embodiment of the present disclosure includes the substrate 110. The substrate 110 may be an insulating transparent material, for example, glass. The substrate 110 may include a concave portion 110p. The concave portion 110p may be formed by irradiating a laser on the substrate 110, and a depth of the concave portion 110p is preferably formed to be thicker than a thickness of the LED 120 such that the LED 120 does not contact an inner surface of the concave portion 110p.

The substrate 110 includes a light emission area where the LED 120 is disposed, and a non-light emission area NEA surrounding the emission area EA. The concave portion 110p is formed to overlap the light emission area EA and may overlap a part of the non-light emission area NEA.

The LED 120 is disposed on the concave portion 110p of the substrate 110. Referring to FIG. 2, the LED 120 may be disposed in the concave portion 110p. The LED 120 includes a buffer layer 121, a first semiconductor layer 123, an active layer 125, a second semiconductor layer 127 and an electrode 129.

The buffer layer 121 at an upper portion of the LED 120 may be made of a GaN based semiconductor material not doped.

The first semiconductor layer 123 is disposed below the buffer layer 121. The first semiconductor layer 123 plays a role to provide an electron to the active layer 125, the first semiconductor layer 123 may be made of a n-GaN based semiconductor material, and the n-GaN based semiconductor material may be GaN, AlGaN, InGaN, AlInGaN or the like. Here, impurities used for doping of the first semiconductor layer 123 may use Si, Ge, Se, Te, C or the like.

The active layer 125 is disposed below the first semiconductor layer 123. The active layer 125 may have a multi quantum well (MQW) structure which has a well layer and a barrier layer having a band gap higher than that of the well layer. The active layer 125 may emit a light in a case that the first semiconductor layer 123 and the second semiconductor layer 127 are applied with voltages or are supplied with currents.

The second semiconductor layer 127 is disposed below the active layer 125. The second semiconductor layer 127 may be made of a p-GaN based semiconductor material, and the p-GaN based semiconductor material may be GaN, AlGaN, InGaN, AlInGaN or the like. Here, impurities used for doping of the second semiconductor layer 127 may use Mg, Zn, Be or the like.

The electrode layer 129 is disposed at a periphery of the LED 120. The electrode layer 129 includes a first electrode pad 129a, a second electrode pad 129b, a first electrode 129c and a second electrode 129d. The first and second electrode pads 129a and 129b may be disposed at an upper portion of the LED 120 and at the same height. The first and second electrode pads 129a and 129b may be disposed to overlap the light emission area EA and the non-light emission area NEA of the substrate 110, and the first and second electrodes 129c and 129d may be disposed to overlap the light emission area EA of the substrate 110. Referring to FIG. 2, the first and second electrode pads 129a and 129b may overlap edges of the concave portion 110p.

The electrode layer 129 may be made of a metal of high reflectance, for example, may include one of Ag, Al, Au, Cr, Ir, Mg, Nd, Ni, Pd, Pt, Rh, Ti and W. Furthermore, the electrode layer 129 may be made of two or more of metals of high reflectance or be formed of a laminated structure with different metals, or be formed of a laminated structure with ITO, IZO or In2O3 and a metal of high reflectance. In some embodiments, the first and second electrode pads 129a and 129b may be made of a metal of high reflectance, and the first and second electrodes 129c and 129d may be made of a metal of high transparency. Accordingly, a light directed over the substrate 110 out of lights emitted from the active layer 125 of the LED 120 may be reflected by the first and second electrode pads 129a and 129b to be directed down the substrate 110, and a light directed to the substrate 110 out of lights emitted from the active layer 125 of the LED 120 may pass through the first and second electrodes 129c and 129d to be output down the substrate 110.

The first electrode pad 129a is electrically connected to a first connection electrode 141, the second electrode pad 129b is electrically connected to a second connection electrode 142. The first electrode 129c is disposed to overlap one side surface of the LED 120 and one surface of the second semiconductor layer 127, and electrically connects the first electrode pad 129a to the second semiconductor layer 127. The second electrode 129d is disposed to overlap the other side surface of the LED 120 and one surface of the first semiconductor layer 123, and electrically connects the second electrode pad 129a to the first semiconductor layer 123.

Not to electrically short-circuit the first semiconductor layer 123 and the second semiconductor layer 127, the electrode layer 129 may be electrically insulated from a side surface of the first semiconductor layer 123 and the buffer layer 121. In other words, the LED 120 may further include a passivation layer, and the passivation layer may be disposed between the first and second electrode pads 129a and 129b and the buffer layer 121 and the passivation layer may be also disposed between the first electrode 129c, and the buffer layer 121 and the first semiconductor layer 123.

An align key 128 is disposed at the upper portion of the LED 120. The align key 128 may be disposed at the same height as the first and second electrode pads 129a and 129b, and may be a material having a magnetic property such that the LED 120 is automatically aligned and disposed at the concave portion 110p of the substrate 110. For example, the align key 128 may be one of aluminum, platinum, gold, manganese, bismuth, silver, copper, iron, nickel and cobalt. Meanwhile, the align key 128 may be removed before forming a first insulating layer 153.

An inside of the concave portion 110p may be filled with a filler 151. In other words, in order that the LED 120 is firmly fixed to the substrate 110, the filler 151 may be disposed between the substrate 110 and the LED 120. The filler 151 is made of a transparent insulating material, for example, may be a resin. A refractive index of the filler 151 may be different from a refractive index of the substrate 110, and thus, a light emitted from the LED 120 can be concentrated down the substrate 110. In other words, a light emitted from the active layer 125 of the LED 120 can be concentrated at a center portion of the LED 120 while passing through the filler 151 and a surface of the concave portion 110p and be thus output down the substrate 110. Therefore, a most of light emitted from the LED 120 can be concentrated to the light emission area EA and be output.

The first insulating layer 153 is disposed on the substrate 110. The first insulating layer 153 may be formed with a single layer of silicon nitride (SiNx) or silicon oxide (SiOx), or formed with multiple layers of silicon nitride (SiNx) and silicon oxide (SiOx). The first insulating layer 153 can improve an adhesive force between layers formed over the first insulating layer 153 and the substrate 110, and can block alkali components and the like leaking from the substrate 110.

A transistor 130 is disposed on the first insulating layer 153. The transistor 130 includes an active electrode 131 made of polysilicon and a gate electrode 135. The transistor 130 shown in FIG. 2 may be a driving transistor, and has a top gate structure that the gate electrode 135 is disposed on the active electrode 131 but it is not limited.

The active electrode 131 of the transistor 130 is disposed on the first insulating layer 153. The active electrode 131 of the transistor 130 includes a third area 131C where a channel is formed when driving the transistor 130, and a first area 131A and a second area 131B at both sides of the third area 131C. The first area 131A may be a source area and the second area 131B may be a drain area, but it is not limited. The third area 131C, the first area 131A and the second area 131B are defined by ion doping (impurity doping).

The active electrode 131 of the transistor 130 includes a polysilicon (poly-Si). In this regard, an amorphous silicon (a-Si) is deposited on the first insulating layer 153, a polysilicon material layer is formed by a method of performing a dehydrogenation process and a crystallization process, and the active layer 131 is formed by patterning the polysilicon material layer.

A second insulating layer 155 is disposed on the first insulating layer 153 and the active electrode 131 of the transistor 130. The second insulating layer 155 may be formed of the same material as the first insulating layer 153, or may be formed with a single layer of silicon nitride (SiNx) or silicon oxide (SiOx), or formed with multiple layers of silicon nitride (SiNx) and silicon oxide (SiOx).

The gate electrode 135 of the transistor 130 is disposed on the second insulating layer 155. The gate electrode 135 may be molybdenum (Mo), and may be disposed to overlap the third area 131C of the active electrode 131 of the transistor 130.

A third insulating layer 157 is disposed on the second insulating layer 155 and the gate electrode 135 of the transistor 130. The third insulating layer 157 may be formed of the same material as the first insulating layer 153 or the second insulating layer 155, or may be formed with a single layer of silicon nitride (SiNx) or silicon oxide (SiOx), or formed with multiple layers of silicon nitride (SiNx) and silicon oxide (SiOx).

The first and second connection electrodes 141 and 142 are disposed on the third insulating layer 157. The first and second connection electrodes 141 and 142 may be made of a conductive metal material, for example, may be formed with a triple-layered structure of titanium (Ti)/aluminum (Al)/titanium (Ti). The first and second connection electrodes 141 and 142 are electrically connected to the first and second pad electrodes 129a and 129b through first and second contact holes 141h and 142h included in the first to third insulating layers 153, 155 and 157, respectively. The first connection electrode 141 disposed on the third insulating layer 157 is disposed to overlap at least a part of the first electrode pad 129a. Meanwhile, the second connection electrode 142 may be disposed between the first insulating layer 153 and the second insulating layer 155, or between the second insulating layer 155 and the third insulating layer 157.

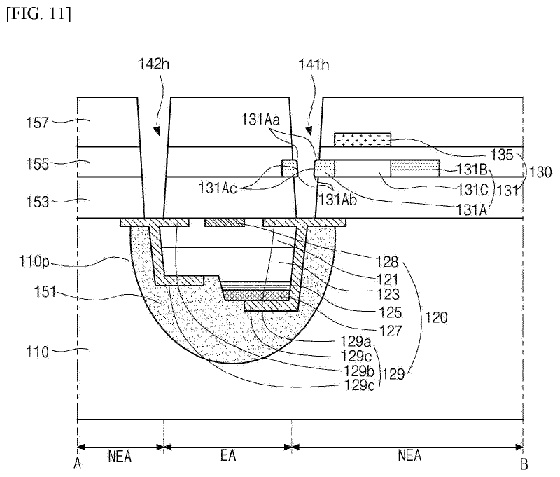

FIG. 3 is a view enlarging an area Al of FIG. 2. Referring to FIGS. 2 and 3, the first and second insulating layers 153 and 155 include the first contact hole (141h of FIG. 11), and the first connection electrode 141 is disposed in the first contact hole 141h. The first contact hole 141h may penetrate at least a part of the first area 131A of the active electrode 131. The first area 131A of the active electrode 131 includes a protrusion portion which protrudes into the first contact hole 141h, and the protrusion portion includes a first protrusion surface 131Aa and a second protrusion surface 131Ab which protrude into the first contact hole 141h. In the enlarging cross-sectional view of FIG. 3, it is shown that the first and second protrusion surfaces 131Aa and 131Ab are disposed at a left side and a right side of an inside of the first contact hole 141h, but it is not limited necessarily. For example, in a vertically cross-sectional view, the first and second protrusion surfaces 131Aa and 131Ab may be disposed at at least one side of the left side and the right side of the inside of the first contact hole 141h.

The protrusion portion of the first area 131A may further include a third protrusion surface 131Ac connected to the first and second protrusion surfaces 131Aa and 131Ab. The third protrusion surface 131Ac may extend in the same direction as an inner surface of the first contact hole 141h, or may be parallel with the inner surface of the first contact hole 141h. In some embodiments, the protrusion portion of the first area 131A may only include the first and second protrusion surfaces 131Aa and 131Ab. In this case, the first and second protrusion surfaces 131Aa and 131Ab may be disposed slantly with respective one ends thereof contacting each other and have a shape with no protrusion surface 131Ac.

The first contact hole 141h may include a first hole penetrating the first area 131A of the active electrode 131 and a second hole penetrating the first insulating layer 153. A diameter of the first hole may be a distance between the third protrusion surfaces 131Ac facing each other, or a distance between the first protrusion surfaces 131Aa facing each other, or a distance between the second protrusion surfaces 131Abc facing each other. At this time, an inside of the first hole and an inside of the second hole are connected to each other, and the first hole and the second hole may completely overlap each other.

The first contact hole 141h may include a third hole penetrating the second insulating layer 155. At this time, insides of the first to third holes are connected to one another. Furthermore, a virtual line connecting center portions of the first to third holes may be in a direction perpendicular to the substrate 110. A maximum diameter of the first hole may be less than a maximum diameter of the second hole, and the maximum diameter of the first hole may be less than a maximum diameter of the third hole. The first protrusion surface 131Aa included in the first area 131A of the active electrode 131 may be exposed to the third hole, and the second protrusion surface 131Ab may be exposed to the second hole.

The first connection electrode 141 is electrically connected to the first area 131A of the active electrode 131 and the first electrode pad 129a of the LED 120 through the first contact hole 141h. Specifically, the first connection electrode 141 may directly contact the protrusion portion of the first area 131A and directly contact at least one of the first to third protrusion surfaces 131Aa, 131Ab and 131Ac.

In the specification of the present disclosure, it is explained that the first electrode pad 129a is electrically connected to the transistor 130, but it is not limited. For example, the second electrode pad 129b of the LED 120 may be electrically connected to the transistor 130. Like this, the first connection electrode 141 and the second connection electrode 142 may be connected to, for example, a high voltage line a common voltage line, respectively, and this may be determined according to a structure of the pixel circuit.

The transistor 130 and at least a part of the LED 120 included in the display device 100 according to one embodiment of the present disclosure may be designed to overlap each other. Therefore, because an unnecessary space can be minimized when designing the pixel P, a resolution can be further improved. Referring to FIG. 2, a fourth insulating layer 159 may be disposed on the third insulating layer 157 and the first and second connection electrodes 141 and 142. The fourth insulating layer 159 may be formed with a single layer of silicon nitride (SiNx) or silicon oxide (SiOx), or formed with multiple layers of silicon nitride (SiNx) and silicon oxide (SiOx). Furthermore, the fourth insulating layer 159 may be made of an organic material, and may compensate for a step on the substrate 110.

FIGS. 4 to 12 are process views of a display device according to one embodiment of the present disclosure.

Because the display device 100 shown in FIGS. 4 to 12 is substantially the same as the display device 100 shown in FIGS. 2 and 3, overlapping explanations of a structure and the like are omitted and explanations are focused on processes.

Referring to FIG. 4, a plurality of concave portions 110p are formed at a substrate 110. Each concave portion 110p is formed with a space enough to accommodate one LED 120, and particularly, is formed such that a diameter of the concave portion 110p, which is formed at a top surface of the substrate 110, is less than a maximum width of the LED 120 including an electrode portion 129.

Referring to FIG. 5, a filling material 151m including the plurality of LEDs 120 is formed on the substrate 110. In order that insides of the plurality of the concave portion 151p are well filled with the filling material 151m, a certain pressure may be applied from over the substrate 110. Meanwhile, it is preferable that the filling material 151m formed on the substrate 110 includes the LEDs 120 a number of which is greater than a number of the concave portions 110p formed at the substrate 110.

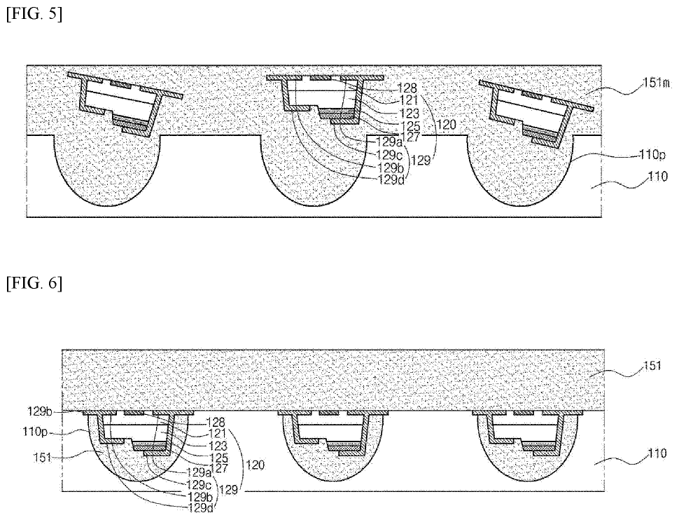

Referring to FIG. 6, one LED 120 is disposed in each concave portion 110p of the substrate 110. When a separate assembly device including a magnetic body is disposed below the substrate 110, the magnetic body and an align key 128 of the LED 120 react with each other, and accordingly, the LED 120 can be disposed at the concave portion 110p.

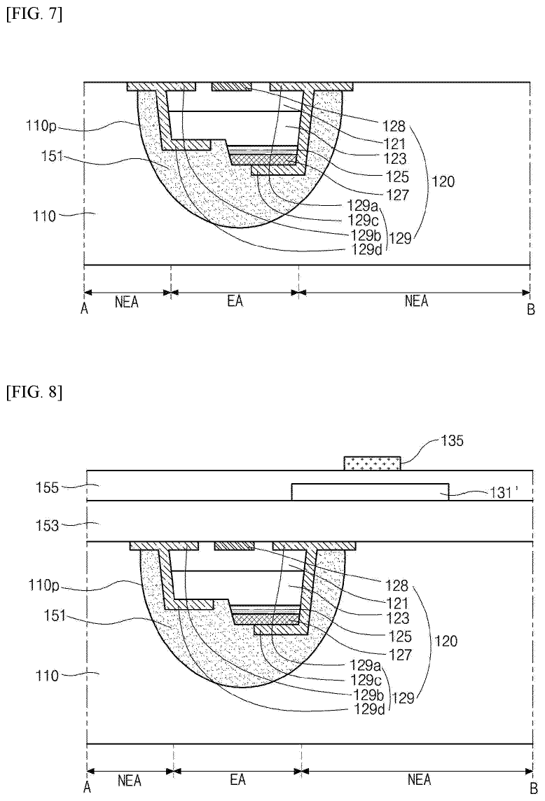

Referring to FIG. 7, the filling material 151m over the substrate 110 is removed. In other words, the filling material 151m over the substrate 110 and the LED 120 is removed such that a filler 151 is disposed only at an inside space of the concave portion 110p. For the conciseness of drawings, in FIGS. 7 to 12, a single LED 120 and a single transistor 130 are merely shown and explained. Meanwhile, after removing the filling material 151m over the substrate 110, a process of removing the align key 128 of the LED 120 may be further performed.

Referring to FIG. 8, a first insulating layer 153 is formed on the substrate 110 including the LED 120 which is placed at the concave portion 110p. Next, an amorphous silicon layer is formed on the first insulating layer 153, then the amorphous silicon layer is crystallized to form a polysilicon layer, and then the polysilicon is patterned to form an active electrode 131′. The crystallization process of the amorphous silicon layer may be performed through an ELA (excimer laser annealing) process or the like.

Next, a second insulating layer 155 and a gate electrode 135 of the transistor 130 are formed sequentially.

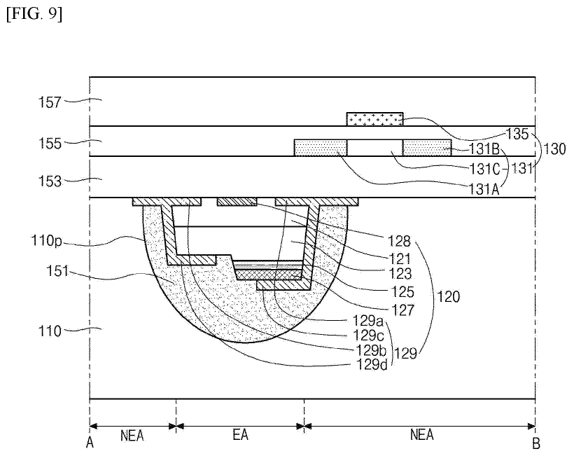

Next, a doping process for the active electrode 131′ of the transistor 130 is performed. Referring to FIG. 9, with the gate electrode 135 of the transistor 130 as a mask, impurities are injected into the active electrode 131′ of the transistor 130 disposed below the gate electrode 135, and thus, a first area 131A and a second area 131B of the active electrode 131, i.e., doping areas can be defined. The definition process of the doping areas may be different according to a P-MOS transistor, an N-MOS transistor or a C-MOS transistor. For example, in case of the N-MOS transistor, a high density doping area may be first formed, and a low density doping area may be then formed. Specifically, after a high density doping area may be defined using a photoresist which has a size greater than the gate electrode 135 of the transistor 130, the photoresist is removed, and a low density doping area (LDD) may be defined with the gate electrode 135 of the transistor 130 as a mask.

In some embodiments, the doping areas including the first area 131A and the second area 131B may be defined before forming the second insulating layer 155. Immediately after forming the active electrode 131 of the transistor 130, it may be doped with impurities using a photoresist.

Next, a third insulating layer 157 is formed on the second insulating layer 155 and the gate electrode 135 of the transistor 130.

The third insulating layer 157 may be made of silicon nitride (SiNx) in order to supply hydrogen to the active electrode 131 of the transistor 130 in a hydrogenation process for the active electrode 131 of the transistor 130 which is made as a subsequent process.

Next, an activation process for the active electrode 131 of the transistor 130 is performed, and a hydrogenation process for the active electrode 131 of the transistor 130 is performed. The activation process makes impurities of the active electrode 131 located at a silicon (Si) lattice, and, by performing the activation process for the active electrode 131 of the transistor 130, a damage of silicon (Si) can be cured. The hydrogenation process is a process of filling a void of polysilicon with hydrogen, and may be performed in a method of diffusing hydrogen included in the third insulating layer 157 through a heat treatment process, for example, may be performed through a heat treatment process at about 350° C. to 380° C. By the hydrogenation process, the active electrode 131 of the transistor 130 can be stabilized.

Next, a first etching is performed for a specific area of the first to third insulating layers 153, 155 and 157 to form first′ and second′ contact holes 141h′ and 142h′.

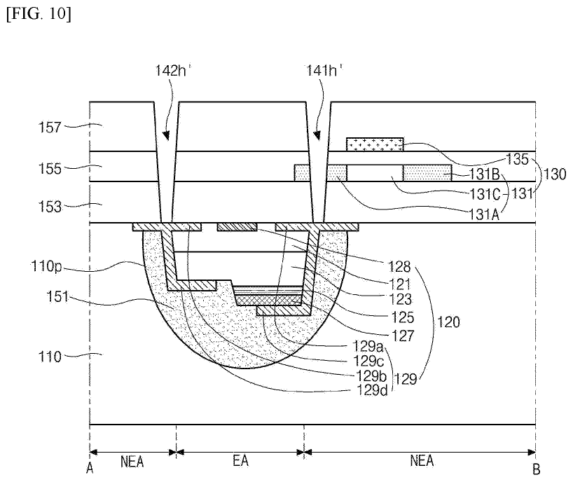

Referring to FIG. 10, the first′ contact hole 141h′ is formed to overlap a first electrode pad 129a on a plane, and the first etching may be a dry etching. At this time, the first′ contact hole 141h′ is formed at all of the first to third insulating layers 153, 155 and 157. Furthermore, the first′ contact hole 141h′ may overlap at least a part of the first area 131A of the transistor 130. The second′ contact hole 142h′ is formed to overlap a first electrode pad 129a on a plane. The second′ contact hole 142h′ may be formed with a dry etching, and may be formed simultaneously with the first contact hole 141h′. At this time, the second′ contact hole 142h′ is formed at all of the first to third insulating layers 153, 155 and 157.

Next, referring to FIG. 11, a second etching is performed for areas of the first′ and second′ contact holes 141h′ and 142h′. Accordingly, first and second contact holes 141h and 142h are formed at the first′ to third insulating layers 153, 155 and 157. The second etching may be a wet etching.

Widths of the first and second contact holes 141h and 142h may be greater than widths of the first′ and second′ contact holes 141h′ and 142h′. Meanwhile, only in the case of forming the first contact hole 141h, the second etching may be performed. In other words, the second etching may not be performed for the second′ contact hole 142h′ shown in FIG. 10 and the second etching may be performed for the first′ contact hole 141h′ shown in FIG. 10, and thus the first contact hole 141h may be formed. In this case, a width of the first contact hole 141h of FIG. 11 may be greater than a width of the first′ contact hole 141h′ of FIG. 10, and a width of the second contact hole 142h of FIG. 11 may be equal to a width of the second′ contact hole 142h′ of FIG. 10.

An etchant of the second etching to form the first contact hole 141h may use a BOE (Buffered Oxide Etchant). In a process of forming the first contact hole 141h, a part of the first area 131A of the transistor 130 may protrude into the first contact hole 141h. In other words, the first area 131A of the transistor 130 may include first and second protrusion surfaces 131Aa and 131Ab. The first and second protrusion surfaces 131Aa and 131Ab may be formed due to a difference of etch rate between inorganic materials forming the first to third insulating layers 153, 155 and 157 and a material of the first area 131A of the transistor 130.

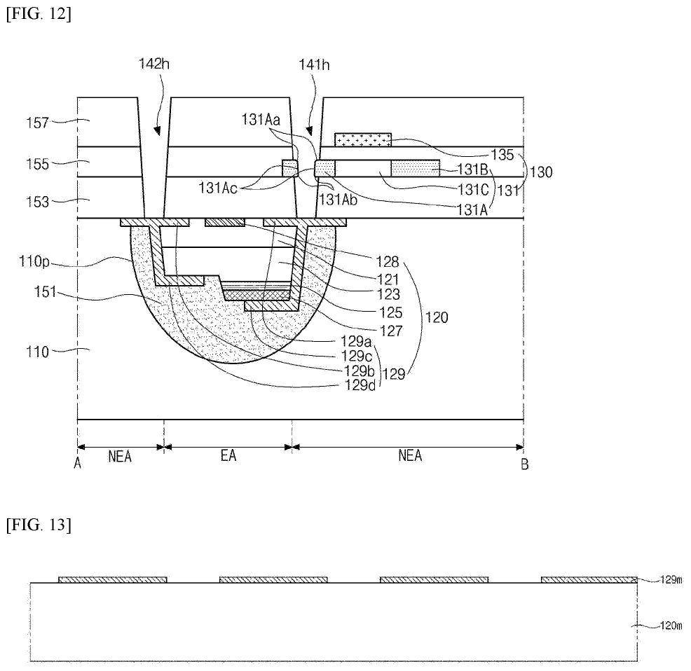

Next, referring to FIG. 12, first and second connection electrodes 141 and 142 are formed on the third insulating layer 157.

The first connection electrode 141 is formed in the first contact hole 141h, and directly contact and is electrically connected to the first area 131A of the transistor and the first electrode pad 129a of the LED 120. Specifically, the first connection electrode 141 may directly contact the first and second protrusion surfaces 131Aa and 131Ab of the first area 131A of the active electrode 131.

Next, a fourth insulating layer 159 is formed on the third insulating layer 157 of the transistor 130.

FIGS. 13 to 18 are process views of an LED according to one embodiment of the present disclosure.

Because the LED 120 shown in FIGS. 13 to 18 is substantially the same as the LED 120 shown in FIG. 12, overlapping explanations of a structure and the like are omitted and explanations are focused on processes.

Referring to FIG. 13, a first electrode pattern layer 129m is formed on a growth substrate 120m. The growth substrate 120m is a substrate where a group III nitride is capable of epitaxial growth. The growth substrate 120m may be made of sapphire (Al₂O₃), silicon carbide or silicon.

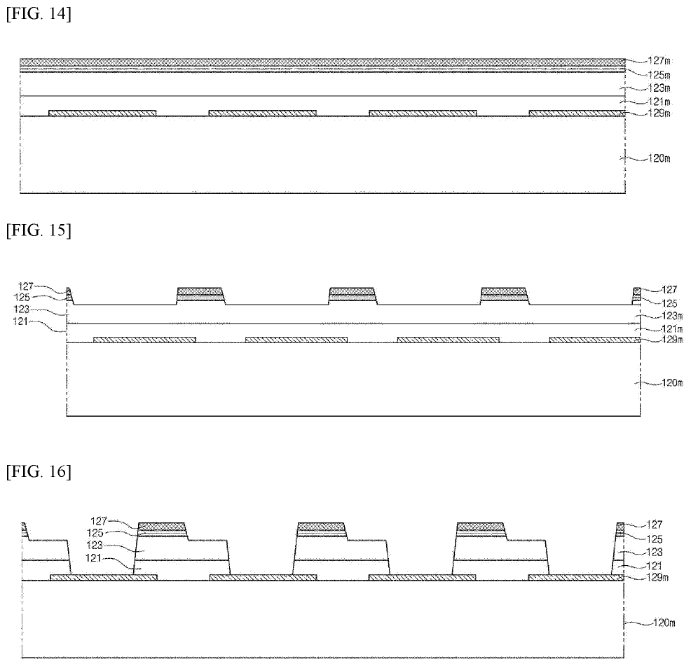

Next, referring to FIG. 14, a buffer material layer 121m, a first semiconductor material layer 123m, an active material layer 125m and a second semiconductor material layer 127m are sequentially formed on the growth substrate 120m and the first electrode pattern layer 129m.

The buffer material layer 121m is formed on the growth substrate 120m in order to mitigate a lattice mismatch and a thermal coefficient difference. Meanwhile, before forming the buffer material layer 121m, an insulating layer may be further formed on the first electrode pattern layer 129m of an area overlapping a light emission area EA.

The buffer material layer 121m, the first semiconductor material layer 123m, the active material layer 125m and the second semiconductor material layer 127m may be formed through a metal organic chemical vapor deposition (MOCVD) process, but it is not limited. For example, it may be formed through a method of a MBE (Molecular Beam Epitaxy), a PECVD (Plasma Enhanced Chemical Vapor Deposition), a VPE (Vapor Phase Epitaxy) or the like.

Next, referring to FIG. 15, parts of the first semiconductor material layer 123m, the active material layer 125m and the second semiconductor material layer 127m are etched to form an active layer 125 and a second semiconductor layer 127 of the LED 120.

Next, referring to FIG. 16, parts of the buffer layer 121m and the first semiconductor material layer 123m are etched to form a buffer layer 121 and a first semiconductor layer 123.

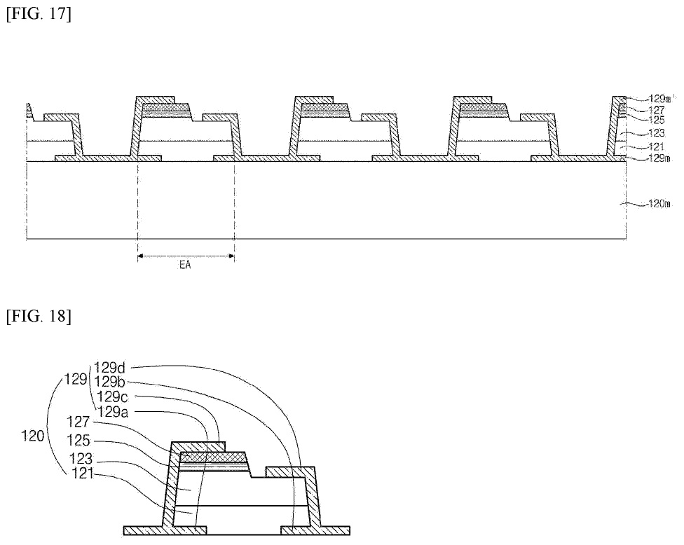

Next, referring to FIG. 17, a second electrode material layer 129m′ is formed on the growth substrate 120m. Meanwhile, before forming the second electrode material layer 129m′, a passivation layer may be further formed between a side surface of each of the buffer layer 121, the first semiconductor layer 123, the active layer 125 and the second semiconductor layer 127, and the second electrode material layer 129m′.

Next, referring to FIG. 18, a part of the first electrode material layer 129m is etched, and the growth substrate 120m is removed, and thus the LED 120 is completed. A first electrode 129c of the LED 120 may directly contact and be electrically connected to a top surface of the second semiconductor layer 127, and a second electrode 129d may directly contact and be electrically connected to a top surface of the first semiconductor layer 123. Furthermore, first and second electrode pads 129a and 129b may be electrically connected to the second semiconductor layer 127 and the first semiconductor layer 121 through the first and second electrodes 129c and 129d, respectively.

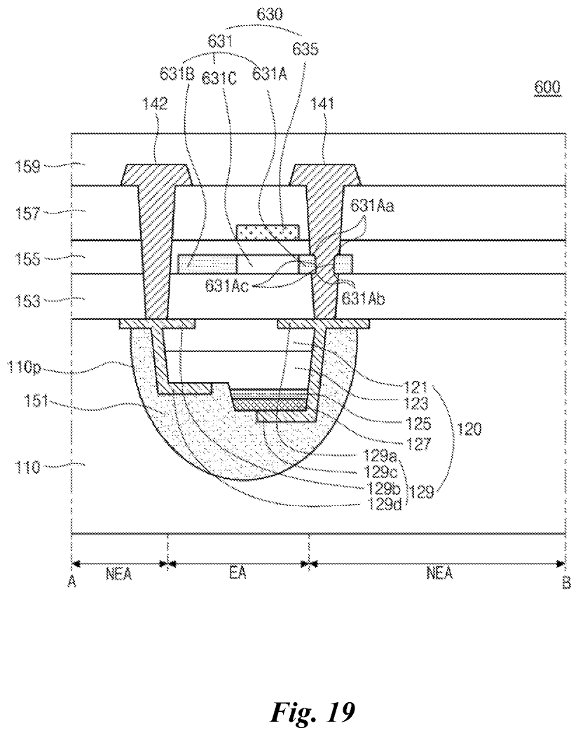

FIG. 19 is a cross-sectional view of a pixel according to another embodiment of the present disclosure.

Because, compared with the display device 100 shown in FIGS. 2, 3 and 4 to 12 and the LED 120 shown in FIGS. 13 to 18, the display device 600 shown in FIG. 19 is different in a position of a transistor 630 and is substantially the same in other components, overlapping explanations are omitted.

The display device 600 according to another embodiment of the present disclosure includes a transistor 630 disposed to overlap a light emission area EA. The transistor 630 includes an active electrode 631 and a gate electrode 635, and the active electrode 631 includes a first area 631A, a second area 631B and a third area 631C. The first to third areas 631A, 631B and 631C may be a source area, a drain area and a channel area, respectively, but it is not limited.

Compared with the display device 100 shown in FIG. 2, the display device 600 shown in FIG. 19 may have a greater overlapping area of the LED 120 and the transistor 630. In other words, the second and third areas 631B and 631C of the transistor 630 shown in FIG. 19 may overlap the light emission area EA of the substrate 110. Furthermore, at least a part of the first area 631A of the transistor 630 may be disposed to overlap the first electrode pad 129a. In some embodiments, a large part of the transistor 630 may overlap the light emission area EA of the substrate 110, and the transistor 630 may completely overlap the concave portion 110p of the substrate 110.

Referring to FIG. 19, a large area of the transistor 630 may overlap the LED 120 on a plane. Therefore, an interval between a plurality of pixels P can be close, and a resolution of a display device can be further improved. Accordingly, the display devices 100 and 600 of the present disclosure can be very advantageous for product groups that require an ultra-high resolution.

Referring to FIGS. 11 and 19, the first and second insulating layers 153 and 155 include the first contact hole 141h, and the first connection electrode 141 is disposed in the first contact hole 141h. The first contact hole 141h may penetrate at least a part of the first area 631A of the active electrode 631. The first area 631A of the active electrode 631 includes a protrusion portion which protrudes into the first contact hole 141h, and the protrusion portion includes a first protrusion surface 631Aa and a second protrusion surface 631Ab which protrude into the first contact hole 141h. In FIG. 19, it is shown that the first and second protrusion surfaces 631Aa and 631Ab are disposed at a left side and a right side of an inside of the first contact hole 141h, but it is not limited necessarily. For example, in a vertically cross-sectional view, the first and second protrusion surfaces 631Aa and 631Ab may be disposed at at least one side of the left side and the right side of the inside of the first contact hole 141h.

The protrusion portion of the first area 631A may further include a third protrusion surface 631Ac connected to the first and second protrusion surfaces 631Aa and 631Ab. The third protrusion surface 631Ac may extend in the same direction as an inner surface of the first contact hole 141h, or may be parallel with the inner surface of the first contact hole 141h. In some embodiments, the protrusion portion of the first area 631A may only include the first and second protrusion surfaces 631Aa and 631Ab. In this case, the first and second protrusion surfaces 631Aa and 631Ab may be disposed slantly with respective one ends thereof contacting each other and have a shape with no protrusion surface 631Ac.

The first contact hole 141h may include a first hole penetrating the first area 631A of the active electrode 631 and a second hole penetrating the first insulating layer 153. A diameter of the first hole may be a distance between the third protrusion surfaces 631Ac facing each other, or a distance between the first protrusion surfaces 631Aa facing each other, or a distance between the second protrusion surfaces 631Abc facing each other. At this time, an inside of the first hole and an inside of the second hole are connected to each other, and the first hole and the second hole may completely overlap each other.

The first contact hole 141h may include a third hole penetrating the second insulating layer 155. At this time, insides of the first to third holes are connected to one another. Furthermore, a virtual line connecting center portions of the first to third holes may be in a direction perpendicular to the substrate 110. A maximum diameter of the first hole may be less than a maximum diameter of the second hole, and the maximum diameter of the first hole may be less than a maximum diameter of the third hole. The first protrusion surface 631Aa included in the first area 631A of the active electrode 631 may be exposed to the third hole, and the second protrusion surface 631Ab may be exposed to the second hole.

The first connection electrode 141 is electrically connected to the first area 631A of the active electrode 631 and the first electrode pad 129a of the LED 120 through the first contact hole 141h. Specifically, the first connection electrode 141 may directly contact the protrusion portion of the first area 631A and directly contact at least one of the first to third protrusion surfaces 631Aa, 631Ab and 631Ac.

In the specification of the present disclosure, it is explained that the first electrode pad 129a is electrically connected to the transistor 630, but it is not limited. For example, the second electrode pad 129b of the LED 120 may be electrically connected to the transistor 630. Like this, the first connection electrode 141 and the second connection electrode 142 may be connected to, for example, a high voltage line and a common voltage line, respectively, and this may be determined according to a structure of the pixel circuit.

The transistor 630 and the LED 120 included in the display device 600 according to one embodiment of the present disclosure may be disposed to overlap each other. Therefore, an unnecessary space can be minimized when designing the pixel P, and accordingly, a resolution of the display device 600 can be further improved.

Furthermore, because the display device 600 according to one embodiment of the present disclosure includes the first connection electrode 141 electrically connecting the transistor 630 to the LED 120, and the first connection electrode 141 directly contacts and is electrically connected to a side surface of the active electrode 613 of the transistor 630, a space to connect the LED 120 to a driving circuit can be minimized. Accordingly, an unnecessary space inside the pixel P can be minimized, and accordingly, a resolution of the display device 600 can be further improved.

One or more embodiments of the present disclosure may be explained as follows.

A display device according to one embodiment of the present disclosure may include a substrate including a plurality of concave portions, light emitting element disposed at respective concave portion of the plurality of concave portions, a first insulating layer disposed on the substrate and the light emitting element, a transistor disposed on the first insulating layer and including an active electrode and a gate electrode, a first hole included in the active electrode, a second hole included in the first insulating layer, and a connection electrode disposed in the first hole and the second hole, wherein the light emitting element may be electrically connected to the active electrode by the connection electrode.

According to another feature of the present disclosure, a first hole may completely overlap a second hole.

According to yet another feature of the present disclosure, an active electrode may include a protrusion portion which protrudes into a first hole.

According to yet another feature of the present disclosure, a connection electrode may directly contact a protrusion portion.

According to yet another feature of the present disclosure, a connection electrode may directly contact at least one of a top surface, a side surface and a bottom surface of a protrusion portion.

According to yet another feature of the present disclosure, at least a part of an active electrode may overlap the light emitting element on a plane.

According to yet another feature of the present disclosure, a gate electrode may overlap a light emitting element on a plane.

According to yet another feature of the present disclosure, an active electrode may be made of a polysilicon material.

According to yet another feature of the present disclosure, a light emitting element may include a first semiconductor layer, an active layer and a second semiconductor layer, and the active electrode may be electrically connected to one of the first semiconductor layer and the second semiconductor layer by a connection electrode.

A display device according to yet another feature of the present disclosure may further include a second insulating layer disposed between a concave portion and a light emitting element.

According to yet another feature of the present disclosure, a light emitting element may include a first electrode electrically connected to a first semiconductor layer and a second electrode electrically connected to a second semiconductor layer, and a connection electrode, a first hole and a second hole may overlap the first electrode or the second electrode.

A display device according to another embodiment of the present disclosure may include a substrate, a light emitting element and a transistor disposed on the substrate, a first electrode electrically connected to a first semiconductor layer of the light emitting element, a second electrode electrically connected to a second semiconductor layer of the light emitting element, and a connection electrode electrically connected to one of the first electrode and the second electrode, wherein the connection electrode may be electrically connected to an active electrode of the transistor, and wherein the connection electrode may penetrate at least a part of the active electrode.

According to another feature of the present disclosure, a transistor may include a gate electrode and an active electrode, the active electrode may include a first area overlapping the gate electrode, and a second area and a third area which are respectively disposed at both ends of the active electrode with the first area interposed therebetween, and a connection electrode may penetrate at least a part of the first area.

According to yet another feature of the present disclosure, a connection electrode may directly contact a side surface of a first area of an active electrode.

A display device according to yet another feature of the present disclosure may further include an insulating layer disposed between an active electrode and a light emitting element, wherein the insulating layer may include at least one contact hole, and wherein the at least one contact hole may overlap a first electrode and a first area.

According to yet another feature of the present disclosure, a contact hole may be perpendicular to a first electrode and a first area.

According to yet another feature of the present disclosure, a substrate may include a concave portion, a light emitting element may be disposed at the concave portion, and a first electrode and a second electrode may overlap peripheries of the concave portion.

A display device according to yet another feature of the present disclosure may further include an insulating material disposed between a concave portion and a light emitting element.

Although the embodiments of the present disclosure have been described in more detail with reference to the accompanying drawings, the present disclosure is not necessarily limited to these embodiments, and various modifications may be made within the scope without departing from the technical spirit of the present disclosure. Accordingly, the embodiments disclosed in the present disclosure are not intended to limit the technical spirit of the present disclosure, but to explain, and the scope of the technical spirit of the present disclosure is not limited by these embodiments. Therefore, it should be understood that the embodiments described above are illustrative in all respects and not restrictive. The protection scope of the present disclosure should be construed by the following claims, and all technical ideas within the scope equivalent thereto should be construed as being included in the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a plurality of concave portions;
light emitting element disposed at respective concave portion of the plurality of concave portions;
a first insulating layer disposed on the substrate and the light emitting element;
a transistor disposed on the first insulating layer and including an active electrode and a gate electrode;
a first hole included in the active electrode;
a second hole included in the first insulating layer; and
a connection electrode disposed in the first hole and the second hole,
wherein the light emitting element is electrically connected to the active electrode by the connection electrode.

2. The display device of claim 1, wherein the first hole completely overlaps the second hole.

3. The display device of claim 1, wherein the active electrode includes a protrusion portion which protrudes into the first hole.

4. The display device of claim 3, wherein the connection electrode directly contacts the protrusion portion.

5. The display device of claim 4, wherein the connection electrode directly contacts at least one of a top surface, a side surface and a bottom surface of the protrusion portion.

6. The display device of claim 1, wherein at least a part of the active electrode overlaps the light emitting element on a plane.

7. The display device of claim 1, wherein the gate electrode overlaps the light emitting element on a plane.

8. The display device of claim 1, wherein the active electrode is made of a polysilicon material.

9. The display device of claim 1, wherein the light emitting element includes a first semiconductor layer, an active layer, and a second semiconductor layer, and
wherein the active electrode is electrically connected to one of the first semiconductor layer and the second semiconductor layer by the connection electrode.

10. The display device of claim 1, further comprising a second insulating layer disposed between the concave portion and the light emitting element.

11. The display device of claim 9, wherein the light emitting element includes a first electrode electrically connected to the first semiconductor layer and a second electrode electrically connected to the second semiconductor layer, and
wherein the connection electrode, the first hole, and the second hole overlap either the first electrode or the second electrode.

12. A display device comprising
a substrate;
a light emitting element and a transistor disposed on the substrate;
a first electrode electrically connected to a first semiconductor layer of the light emitting element;
a second electrode electrically connected to a second semiconductor layer of the light emitting element; and
a connection electrode electrically connected to one of the first electrode and the second electrode,
wherein the connection electrode is electrically connected to an active electrode of the transistor, and
wherein the connection electrode penetrates at least a part of the active electrode.

13. The display device of claim 12, wherein the transistor includes a gate electrode and the active electrode,
wherein the active electrode includes a first area overlapping the gate electrode, and a second area and a third area which are respectively disposed at both ends of the active electrode with the first area interposed therebetween, and
wherein the connection electrode penetrates at least a part of the first area.

14. The display device of claim 13, wherein the connection electrode directly contacts a side surface of the first area of the active electrode.

15. The display device of claim 13, further comprising an insulating layer disposed between the active electrode and the light emitting element,
wherein the insulating layer includes at least one contact hole, and
wherein the at least one contact hole overlaps the first electrode and the first area.

16. The display device of claim 15, wherein the contact hole is perpendicular to the first electrode and the first area.

17. The display device of claim 12, wherein the substrate includes a concave portion,
wherein the light emitting element is disposed at the concave portion, and
wherein the first electrode and the second electrode overlap peripheries of the concave portion.

18. The display device of claim 17, further comprising an insulating material disposed between the concave portion and the light emitting element.

19. A display device comprising:
a substrate having a first surface, the substrate including a plurality of concave portions extending below the first surface;
a light emitting element disposed in respective concave portion of the plurality, the light emitting element including a first electrode pad and a second electrode pad, a top surface of the first electrode pad and a top surface of the second electrode pad being coplanar with the first surface of the substrate;
a first insulating layer disposed on the first surface of the substrate and the top surfaces of the first and second electrode pads of the light emitting element;
a transistor disposed on the first insulating layer and including an active electrode and a gate electrode; and
a connection electrode extending through the active electrode and contacting the top surface of the first electrode pad of the light emitting element.

20. The display device of claim 19, wherein the active electrode includes a first protrusion portion and a second protrusion portion spaced apart and facing the first protrusion portion, the first protrusion portion and the second protrusion portion each protruding towards each other, and
wherein the connection electrode extends through a space between the first protrusion portion and the second protrusion portion.
